(19) United States
(12) Patent Application Publication
(10) Pub. No.: US 2025/0327726 A1
(43) Pub. Date: Oct. 23, 2025

(54) SUPERFLUID HELIUM BASED LIQUID THERMAL SWITCH FOR A DYNAMIC NUCLEAR POLARIZATION SYSTEM

(71) Applicant: GE Precision Healthcare LLC, Waukesha, WI (US)

(72) Inventors: Ernst Wolfgang Stautner, Niskayuna, NY (US); Arnaud Comment, Cambridge (GB); Albert Po Fu Chen, Taichung City (TW); Rui Chen, Clifton Park, NY (US); Daniel John Kindness, Oxford (GB); Justin Yat Cheong Lau, Tampa, FL (US); James Richard Trigger, Rotterdam Junction, NY (US)

(21) Appl. No.: 18/643,782

(22) Filed: Apr. 23, 2024

(51) Int. Cl. G01N 1/42; G01N 24/08

(52) U.S. Cl. CPC G01N 1/42; G01N 24/08

(57) ABSTRACT

A cooling system associated with a dynamic nuclear polarization system includes a cryogenic chamber including a cryogenic fluid. The cooling system also includes a pot positioned within the cryogenic chamber, the pot being at least partially surrounded by the cryogenic fluid. The cooling system further includes a removable sample sleeve inserted into the pot so that a lower portion of the removable sample sleeve is positioned in the pot and an upper portion of the removable sample sleeve protrudes out of the pot. The cooling system even further includes a liquid thermal switch configured to be disposed between and directly contact an inner surface of a bottom of the pot and a bottom surface of the lower portion of the removable sample sleeve, wherein the liquid thermal switch includes superfluid helium.

### BACKGROUND

The subject matter disclosed herein relates to diagnostic medical imaging, and more particularly, to dynamic nuclear polarization systems.

Dynamic nuclear polarization (DNP) is a technique that is used to generate an excess of a nuclear spin orientation relative to another spin orientation, which is sometimes referred to as hyperpolarization. The excess of one spin orientation over another is reflected by an increase in the signal-to-noise ratio of measurements in nuclear magnetic resonance systems such as magnetic resonance imaging (MRI) systems.

DNP often involves cooling samples to particularly low temperatures. For instance, DNP systems may include liquid cryogen (e.g., liquid helium) baths used to cool samples to very low temperatures, sometimes below four Kelvin. Maintenance on a cooling system for the DNP system may take a number of days. In addition, the mechanical configuration of the cooling system may make servicing it more difficult.

### SUMMARY

Certain embodiments commensurate in scope with the originally claimed subject matter are summarized below. These embodiments are not intended to limit the scope of the claimed subject matter, but rather these embodiments are intended only to provide a brief summary of possible forms of the subject matter. Indeed, the subject matter may encompass a variety of forms that may be similar to or different from the embodiments set forth below.

In one embodiment, a cooling system associated with a dynamic nuclear polarization system is provided. The cooling system is configured to cool a sample to a temperature suitable for dynamic nuclear polarization to be carried out on the sample while the sample is in the cooling system. The cooling system includes a cryogenic chamber including a cryogenic fluid. The cooling system also includes a pot positioned within the cryogenic chamber, the pot being at least partially surrounded by the cryogenic fluid. The cooling system further includes a removable sample sleeve inserted into the pot so that a lower portion of the removable sample sleeve is positioned in the pot and an upper portion of the removable sample sleeve protrudes out of the pot. The removable sample sleeve is configured to define a sample path for the sample within the cryogenic chamber that is isolated from other parts of the cooling system. The cooling system even further includes a liquid thermal switch configured to be disposed between and directly contact an inner surface of a bottom of the pot and a bottom surface of the lower portion of the removable sample sleeve, wherein the liquid thermal switch includes superfluid helium.

In another embodiment, a method for regulating a liquid thermal switch for a cooling system associated with a dynamic nuclear polarization system is provided. The cooling system is configured to cool a sample to a temperature suitable for dynamic nuclear polarization to be carried out on the sample while the sample is in the cooling system. The method includes opening, via a processor, a vacuum valve to evacuate an interspatial space between a pot and a removable sample sleeve while a shut valve is closed, wherein the pot is positioned within a cryogenic chamber, the pot is at least partially surrounded by a cryogenic fluid, and the removable sample sleeve is inserted into the pot so that a lower portion of the removable sample sleeve is positioned in the pot and an upper portion of the removable sample sleeve protrudes out of the pot, wherein the removable sample sleeve is configured to define a sample path for the sample within the cryogenic chamber that is isolated from other parts of the cooling system and wherein the interspatial space is coupled to a main conduit coupled to the pot, the vacuum valve is disposed along a first interconnecting conduit coupled to the main conduit and a vacuum pump, and the shut valve is disposed along a second interconnecting conduit extending between the main conduit and a buffer tank holding a gaseous helium. The method also includes after evacuating the interspatial space, closing, via the processor, the vacuum valve and then opening, via the processor, the shut valve to enable flow gaseous helium into the interspatial space from the buffer tank via the main conduit. The method further includes monitoring, via the processor, pressure as the gaseous helium flows into the interspatial space and cools down with the pressure lowering. The method even further includes closing, via the processor, the shut valve after helium becomes superfluid helium at a temperature of approximately 1 Kelvin forming the liquid thermal switch disposed between and directly contacting an inner surface of a bottom of the pot and a bottom surface of the lower portion of the removable sample sleeve.

In a further embodiment, a non-transitory computer-readable medium, the computer-readable medium including processor-executable code that when executed by a processing system including one or more processors, causes the processing system to perform actions. The actions include opening a vacuum valve to evacuate an interspatial space between a pot and a removable sample sleeve while a shut valve is closed, wherein the pot is positioned within a cryogenic chamber, the pot is at least partially surrounded by a cryogenic fluid, and the removable sample sleeve is inserted into the pot so that a lower portion of the removable sample sleeve is positioned in the pot and an upper portion of the removable sample sleeve protrudes out of the pot. The interspatial space is coupled to a main conduit coupled to the pot, the vacuum valve is disposed along a first interconnecting conduit coupled to the main conduit and a vacuum pump, and the shut valve is disposed along a second interconnecting conduit extending between the main conduit and a buffer tank holding a gaseous helium, and wherein the pot and the removable sample sleeve are part of a cooling system associated with a dynamic nuclear polarization system. The cooling system is configured to cool a sample to a temperature suitable for dynamic nuclear polarization to be carried out on the sample while the sample is in the cooling system. The actions also include, after evacuating the interspatial space, closing the vacuum valve and then opening the shut valve to enable flow gaseous helium into the interspatial space from the buffer tank via the main conduit. The actions further include monitoring pressure as the gaseous helium flows into the interspatial space and cools down with the pressure lowering. The actions even further include closing the shut valve after helium becomes superfluid helium at a temperature of approximately 1 Kelvin forming a liquid thermal switch disposed between and directly contacting an inner surface of a bottom of the pot and a bottom surface of the lower portion of the removable sample sleeve, and wherein the removable sample sleeve is configured to define a sample path for the sample within the cryogenic chamber that is isolated from other parts of the cooling system.

### BRIEF DESCRIPTION OF THE DRAWINGS

These and other features, aspects, and advantages of the present disclosed subject matter will become better understood when the following detailed description is read with reference to the accompanying drawings in which like characters represent like parts throughout the drawings, wherein:

FIG. 1 is a schematic diagram of a cooling system (e.g., having a liquid thermal switch) used to cool one or more samples, in accordance with aspects of the present disclosure;

FIG. 2 is a schematic diagram of the cooling system in FIG. 1 that includes a sample that is being lowered towards a pot of the cooling system, in accordance with aspects of the present disclosure;

FIG. 3 is a schematic diagram of the cooling system in FIG. 1 that includes a sample cooled via cryogenic fluid, in accordance with aspects of the present disclosure;

FIG. 4 is a schematic diagram of the cooling system in FIG. 1 that has a liquid thermal switch removed, in accordance with aspects of the present disclosure;

FIG. 5 is a schematic diagram of a portion of the cooling system in FIG. 1 (e.g., with the liquid thermal switch absent), in accordance with aspects of the present disclosure;

FIG. 6 is a schematic diagram of a portion of the cooling system in FIG. 1 (e.g., with the liquid thermal switch present), in accordance with aspects of the present disclosure;

FIG. 7 is a schematic diagram of a portion of the cooling system in FIG. 1 (e.g., with a removable sample sleeve having thermal radiation baffles), in accordance with aspects of the present disclosure;

FIG. 8 is a flowchart of a method for forming a thermal heat switch in the cooling system 10 in FIG. 1, in accordance with aspects of the present disclosure;

FIG. 9 is a flowchart of a method for removing a thermal heat switch in the cooling system 10 in FIG. 1 (e.g., for servicing a removable sample sleeve), in accordance with aspects of the present disclosure; and

FIG. 10 is a graph depicting temperatures at near a top portion (e.g., top flange) of a cryogenic vessel that a removable sample sleeve is partially disposed within and a bottom of the removable sample sleeve in a presence of a liquid thermal switch, in accordance with aspects of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present subject matter, the articles “a,” “an,” “the,” and “said” are intended to mean that there are one or more of the elements. The terms “comprising,” “including,” and “having” are intended to be inclusive and mean that there may be additional elements other than the listed elements. Furthermore, any numerical examples in the following discussion are intended to be non-limiting, and thus additional numerical values, ranges, and percentages are within the scope of the disclosed embodiments.

The present disclosure provides for a liquid thermal switch for a cooling system associated with a dynamic nuclear polarization system. The liquid thermal switch is formed by a liquid medium (e.g., superfluid helium) between two contact surfaces that compensate for surface irregularities. The utilization of the liquid thermal switch enables the removal of a thermal switch made of mechanical parts and any other mechanical components associated with such a thermal switch. In particular, the liquid thermal switch makes perfect contact (between the two contact surfaces) in a cryogenic environment without mechanical means utilizing the high thermal conductivity of superfluid helium. Superfluid helium has infinite thermal conductivity below 2.5 Kelvin. Since the thermal conductivity for superfluid helium cannot be measured, it is defined in literature as a factor of 1000 higher than copper at this temperature (i.e., below 2.5 Kelvin). Although the following is discussed in the context of a dynamic nuclear polarization system the utilization of the superfluid helium (e.g., as a liquid thermal switch) may be utilized in other applications (e.g., quantum computers, accelerator magnets, etc.). Compared to a solid switch, a liquid thermal switch changes shape and phase and can assume different forms and shapes, while it is not confined to a housing.

The disclosed embodiments include a cooling system associated with a dynamic nuclear polarization system that is configured to cool a sample to a temperature suitable for dynamic nuclear polarization to be carried out on the sample while the sample is in the cooling system. The cooling system includes a cryogenic chamber including a cryogenic fluid. The cooling system also includes a pot (e.g., interspatial tube) positioned within the cryogenic chamber, the pot being at least partially surrounded by the cryogenic fluid. The cooling system further includes a removable sample sleeve inserted into the pot so that a lower portion of the removable sample sleeve is positioned in the pot and an upper portion of the removable sample sleeve protrudes out of the pot. The removable sample sleeve is configured to define a sample path for the sample within the cryogenic chamber that is isolated from other parts of the cooling system. The cooling system even further includes a liquid thermal switch configured to be disposed between and directly contact an inner surface of a bottom of the pot and a bottom surface of the lower portion of the removable sample sleeve, wherein the liquid thermal switch includes superfluid helium.

In certain embodiments, the liquid thermal switch is configured to be disposed within a gap between the inner surface of the bottom of the pot and the bottom surface of the lower portion of the removable sample sleeve. In certain embodiments, the gap is between 1 to 3 millimeters.

In certain embodiments, the liquid thermal switch is configured to keep a same temperature at the inner surface of the bottom of the pot and at the bottom surface of the lower portion of the removable sample sleeve by providing infinite thermal conductivity between the inner surface of the bottom of the pot and the bottom surface of the lower portion of the removable sample sleeve at a temperature below 2.5 Kelvin. In certain embodiments, the liquid thermal switch is configured to compensate for surface irregularities that cause the inner surface of the bottom of the pot and the bottom surface of the lower portion of the removable sample sleeve to not be perfectly parallel along a length of interface between the inner surface and the bottom surface. In certain embodiments, the liquid thermal switch is configured to provide zero or near zero thermal resistance between the inner surface of the bottom of the pot and the bottom surface of the lower portion of the removable sample sleeve. The liquid thermal switch is configured to be utilized with different gap heights (which cannot be accomplished with a solid switch). Thus, the liquid thermal switch can compensate for assembly (e.g., build) tolerances between the inner surface of the bottom of the pot and at the bottom surface of the lower portion of the removable sample sleeve.

In certain embodiments, the cooling system is configured to remove the liquid thermal switch to decouple the inner surface of the bottom of the pot and the bottom surface of the lower portion of the removable sample sleeve. In certain embodiments, the cooling system is configured to allow the bottom surface of the lower portion of the removable sample sleeve to reach at least 300 Kelvin for servicing when the liquid thermal switch is removed.

In certain embodiments, the removable sample sleeve includes a wall and one or more thermal radiation baffles disposed about and extending away from the wall toward the pot. The one or more thermal radiation baffles are disposed on the upper and the lower portion of the removable sample sleeve above where the liquid thermal switch is located and are configured to keep superfluid helium of the liquid thermal switch between the inner surface of the bottom of the pot and the bottom surface of the lower portion of the removable sample sleeve.

The disclosed embodiments also include a method for regulating a liquid thermal switch for a cooling system associated with a dynamic nuclear polarization system is provided. The cooling system is configured to cool a sample to a temperature suitable for dynamic nuclear polarization to be carried out on the sample while the sample is in the cooling system. The method includes opening, via a processor, a vacuum valve to evacuate an interspatial space between a pot and a removable sample sleeve while a shut valve is closed, wherein the pot is positioned within a cryogenic chamber, the pot is at least partially surrounded by a cryogenic fluid, and the removable sample sleeve is inserted into the pot so that a lower portion of the removable sample sleeve is positioned in the pot and an upper portion of the removable sample sleeve protrudes out of the pot, wherein the removable sample sleeve is configured to define a sample path for the sample within the cryogenic chamber that is isolated from other parts of the cooling system and wherein the interspatial space is coupled to a main conduit coupled to the pot, the vacuum valve is disposed along a first interconnecting conduit coupled to the main conduit and a vacuum pump, and the shut valve is disposed along a second interconnecting conduit extending between the main conduit and a buffer tank holding a gaseous helium. The method also includes after evacuating the interspatial space, closing, via the processor, the vacuum valve and then opening, via the processor, the shut valve to enable flow gaseous helium into the interspatial space from the buffer tank via the main conduit. The method further includes monitoring, via the processor, pressure as the gaseous helium flows into the interspatial space and cools down with the pressure lowering. The method even further includes closing, via the processor, the shut valve after helium becomes superfluid helium at a temperature of approximately 1 Kelvin forming the liquid thermal switch disposed between and directly contacting an inner surface of a bottom of the pot and a bottom surface of the lower portion of the removable sample sleeve.

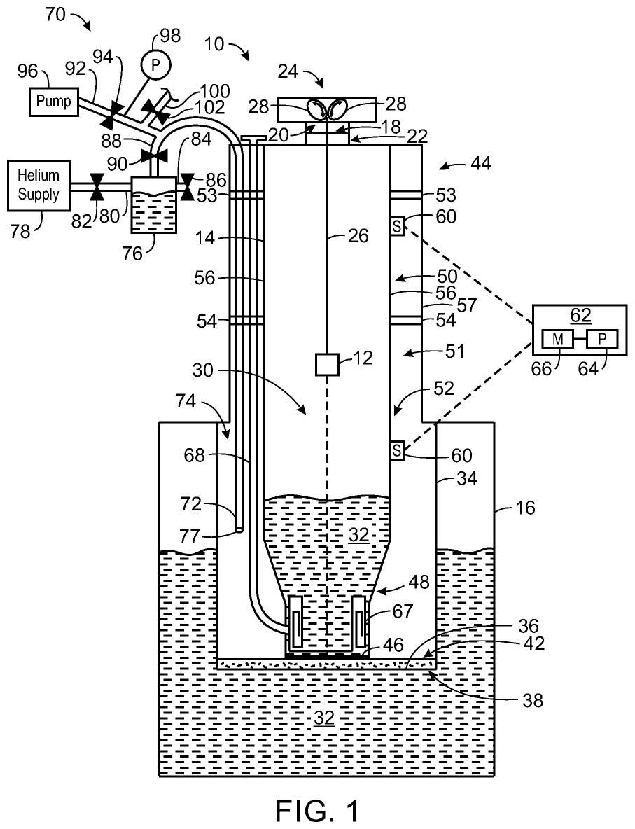

Keeping the foregoing in mind, FIG. 1 is a schematic diagram of a cooling system 10 used to cool one or more samples 12 that may be included in a storage container (e.g., a vial). The cooling system 10 may be included in a dynamic nuclear polarization (DNP) system. The sample 12 may include chemical compounds, solutions, and the like. For example, the sample 12 may include pyruvate, pyruvic acid, urea, uric acid, and/or glycerol. Moreover, the cooling system 10 includes a removable sample sleeve 14 (e.g., removable sample sleeve tube) that may enable more rapid de-icing procedures (i.e., easier de-icing) for the cooling system 10 as compared to other configurations.

During operation of the system 10, the sample 12 may be cooled via a cryogenic chamber 16 (e.g., a liquid cryogen bath) into which the sample 12 may be placed. To facilitate transitioning the sample 12 from the room temperature environment into the cooling system 10, the cooling system 10 includes an airlock chamber 18 into which the sample 12 may be inserted. The airlock chamber 18 may be used to maintain the sample 12 at a suitable pressure. For instance, in some cases, the airlock chamber 18 may be utilized to keep the sample at a pressure that is lower than standard atmospheric pressure. The airlock chamber 18 may include one or more baffles 20 and gate valve 22 that aid in maintaining a certain pressure within the cooling system 10.

Moreover, the system may also include a positioning system 24 that may be used to move the sample 12 within the cooling system 10. For instance, the sample 12 may be coupled to a line 26 (e.g., a hollow tube or vial stick), and the line 26 may be coupled to pitch wheels 28 of the positioning system 24. Rotation of the pitch wheels 28 causes the sample 12 to be moved along a sample path 30 toward and away from the cryogenic chamber 16.

The sample 12 may be cooled within the cooling system 10 via convection and conduction. For example, as the sample 12 is moved closer to the cryogenic chamber 16 but not placed in a cryogenic fluid 32 (e.g., liquid helium), the cooling may occur by way of convection, and the sample 12 may be placed within the cryogenic fluid 32 to be cooled via conduction.

In addition to the cryogen fluid 32, the cryogenic chamber 16 includes a pot 34 (e.g., interspatial tube). The pot 34 forms an enclosed volume within the cryogenic chamber 16. The pot 34 may be thermally insulated so as to maintain a constant temperature within the pot 34. By way of non-limiting example, in certain embodiments, the temperature in the pot 34 is less than 1 Kelvin. More specifically, in certain embodiments the temperature in the pot 34 is between about 0.75 K and 0.95 K. Moreover, a portion of the pot 34 may directly contact the cryogenic fluid 32 that is stored within the cryogenic chamber 16.

Turning the discussion now to the removable sample sleeve 14, the removable sample sleeve 14 may be positionable within the cooling system 10. More specifically, the removable sample sleeve 14 may be disposed within an upper portion 44 of the cooling system 10 as well as the pot 34 of the cryogenic chamber 16. In other words, the removable sample sleeve 14 has a geometry and size appropriate for the cooling system 10. The removable sample sleeve 14 may be made from various metals and metal alloys. For instance, the removable sample sleeve may be made from nickel-chromium based alloys (e.g., Inconel®), stainless steel, titanium, titanium-aluminum alloys, and/or any combination thereof. Additionally, a bottom surface 46 of a lower portion 48 of the removable sample sleeve 14 may be copper-plated, gold-plated, or copper and gold-plated.

The removable sample sleeve 14 includes a body portion 50, and the lower portion 48 that is in thermal communication with a liquid thermal switch 42 (e.g., in the form of superfluid helium). That is, as illustrated, the lower portion 48 of the removable sample sleeve 14 may be positioned within the pot 34, while an upper portion 51 of the body portion 50 protrudes out of the pot 34. In some embodiments, the upper portion 51 may form a seal at a transition point 52 between the upper portion 51 and lower portion 48 of the removable sample sleeve 14. For instance, formation of a seal at the transition point 52 may be achieved via an attachment that may be coupled to the removable sample sleeve 14. Additionally, the body portion 50 include a portion of the upper portion 51 and lower portion 48. For instance, the upper portion 51 may be a portion the body portion 50 that is positioned outside of the pot 34, while the lower portion 48 may include a portion of the body portion 50 that is located within the pot 34.

The removable sample sleeve 14 defines the sample path 30 within the cooling system 10, and the sample path 30 is isolated from other parts of the cooling system 10, such as the cryogenic fluid 32 in the cryogenic chamber 16 that is outside of the pot 34. As illustrated, the sample path 30 extends through the upper portion 51, body portion 50 and lower portion 48 of the removable sample sleeve 14. That is, the sample 12 may be raised and lowered (e.g. via the positioning system 24) within the removable sample sleeve 14. Additionally, the lower portion 48 includes a certain amount of the cryogenic fluid 32 separate from the cryogenic fluid 32 in the cryogenic chamber 16 outside of the pot 34. The sample 12 may be moved into the cryogenic fluid 32 contained in the lower portion 48 to conductively cool the sample 12.

The removable sample sleeve 14 may be secured in place via a first set of links 53 and a second set of links 54. More specifically, the first set of link 53 and the second set of links 54 may include beryllium copper springs or other thermally conducing cryogenic springs or fingerstock, and the first set of links 53 and second set of link 54 may physically and thermally connect the wall 56 of the removable sample sleeve 14 to an outer tube 57 that surrounds the removable sample sleeve 14. Due to the first and second sets of links 53, 54, the wall 56 and outer tube 57 may be equivalent in temperature. Additionally, the first set of link 53 and second set of link 54 may be maintained at a constant temperature by a cryocooler.

Generally, the temperature within the cooling system 10 is lower in areas closer to, and within, the cryogenic chamber 16. For example, the temperature in the area of the cooling system 10 between the gate valve 22 and the first set of links 53 is generally about 40 K or warmer. The temperature in the area between the first set of links 53 and the second set of links 54 generally ranges from about 4 K to 40 K. And, as discussed above, the temperature in the pot 34, in which the lower portion 48 of the removable sample sleeve 14 is positioned, may be less than about 1 K. That is, as the sample 12 is lowered along the sample path 30 towards and into the pot 34, the sample becomes subjected to lower and lower temperatures.

As mentioned above, the lower portion 48 of the removable sample sleeve 14 is in thermal communication with the liquid thermal switch 42 formed of superfluid helium. In particular, the liquid thermal switch 42 is disposed between and directly contacts an inner surface 36 of a bottom 38 of the pot 34 and the bottom surface 46 of the lower portion 48 of the removable sample sleeve 14. More specifically, the liquid thermal switch 42 is disposed within a gap between the inner surface 36 of the bottom 38 of the pot 34 and the bottom surface 46 of the lower portion 48 of the removable sample sleeve 14. In certain embodiments, the gap is between 1 to 3 millimeters. In certain embodiments, the amount of superfluid helium forming the liquid thermal switch 42 may range between approximately 2.5 to 4 milliliters.

The liquid thermal switch 42 provides open superfluid bath cooling. The liquid thermal switch 42 keeps a same temperature at the inner surface 36 of the bottom 38 of the pot 34 and at the bottom surface 46 of the lower portion 48 of the removable sample sleeve 14 by providing infinite thermal conductivity between the inner surface 36 and the bottom surface 46 at a temperature below 2.5 Kelvin (e.g., at approximately 1 Kelvin where the liquid thermal switch 42 interacts with the inner surface 36 and the bottom surface 46). In particular, the liquid thermal switch 42 eliminates temperature differences, via the infinite thermal conductivity, between the inner surface 36 and the bottom surface 46 at a temperature of approximately 1 Kelvin. Due to its fluidic nature, the liquid thermal switch 42 is self-adjusting. Thus, if there is a difference in gap size along a length of the interface between the inner surface 36 and the bottom surface 46, the liquid thermal switch 42 can adjust or compensate. In addition, the liquid thermal switch 42 compensates for surface irregularities that cause the inner surface 36 of the bottom 38 of the pot 34 and the bottom surface 46 of the lower portion 48 of the removable sample sleeve 14 to not be perfectly parallel along a length of interface between the inner surface 36 and the bottom surface 46. Further, the liquid thermal switch 42 compensates for build tolerances between the inner surface 36 and the bottom surface 46. The liquid thermal switch 42 provides zero or near zero thermal resistance (e.g., due to a lack of contact resistances) between the inner surface 36 and the bottom surface 46. As a result, bigger heat loads can be tolerated down the removable sample sleeve 14.

In certain embodiments, the removable sample sleeve 14 includes the wall 56 and one or more thermal radiation baffles disposed about and extending away from the wall 56 toward the pot 34. The one or more thermal radiation baffles are disposed on the lower portion 48 of the removable sample sleeve 14 above where the liquid thermal switch 42 is located and are configured to keep superfluid helium of the liquid thermal switch 42 between the inner surface 36 of the bottom 38 of the pot 34 and the bottom surface 46 of the lower portion 48 of the removable sample sleeve 14.

As noted above, the cooling system 10 may be for DNP applications. In some embodiments, the cooling system 10 may include components used to perform DNP. For example, in the illustrated embodiment, the cooling system 10 includes nuclear magnetic resonance (NMR) coils 67 and a waveguide 68. The sample 12 may be placed within the NMR coil 67, and data regarding the sample 12 may be collected. More specifically, electromagnetic radiation (e.g., microwaves) produced by the NMR coil 67 is directed onto the sample 12 and may be received by the NMR coil 67. The waveguide 68 may be used to guide the electromagnetic radiation to and/or from the NMR coils 67.

The cooling system 10 includes a system 70 for installing (e.g., forming), maintenance, and removal of the liquid thermal switch 42. The cooling system 10 includes a conduit 72 (e.g., main conduit) that extends into and is coupled to interspatial space 74 between the pot 34 and the removable sample sleeve 14 that provides helium from a tank 76 (e.g., buffer tank). The conduit 72 includes an opening 77 (e.g., inlet/outlet) that may be disposed at a number different locations within the interspatial space 74 relative to the removable sample sleeve 14. The tank 76 stores gaseous helium provided by a helium supply 78 via a conduit 80 when a valve 82 (e.g., fill valve) disposed along the conduit 80 is open. The valve 82 regulates flow of helium along the conduit 80. Another conduit 84 is coupled to the tank 76. A valve 86 (e.g., buffer tank safety valve) is disposed along the conduit 84.

Conduit 88 (e.g., interconnecting conduit) is coupled to the conduit 72. A valve 90 (e.g., shut valve) is disposed along the conduit 88. The valve 90 regulates flow of helium between the tank 76 and the conduit 72 (and, thus, the interspatial space 74). Another conduit 92 (e.g., interconnecting conduit) is coupled to the conduit 72 (e.g., at a location between the valve 90 and the interspatial space 74. A valve 94 (e.g., vacuum valve) is disposed along the conduit 92. The conduit 92 is coupled to a pump 96. When the pump 96 is activated and the valve 94 is open, the interspatial space 74 is evacuated and the liquid thermal switch 42 is removed via the conduit 72. The liquid thermal switch 42 (e.g., via conduit 72) may be removed in case of need to service space of the removable sample sleeve 14. When the valve 82 is open and the valve 94 is closed (with the inner surface 36 at operating temperature (i.e., at least 4 Kelvin) and once the cryogenic chamber 16 is cooled down to 1 Kelvin), helium flows into interspatial space 74 and cools down with the pressure lowering. At 1 Kelvin, in the gap between the between the inner surface 36 of the bottom 38 of the pot 34 and the bottom surface 46 of the lower portion 48 of the removable sample sleeve 14, the helium becomes superfluid helium and forms the liquid thermal switch 42. A pressure sensor 98 is disposed along the conduit 92 to monitor a pressure along the conduit 92. A conduit 100 is coupled to the conduit 92. A valve 102 (e.g., safety valve) is disposed along the conduit 100. The valve 102 protects interspatial space 74 in case of a fault condition (e.g., quench, cryo vacuum failure, etc.).

As noted, the cooling system 10 (via the system 70) is configured to remove the liquid thermal switch 42 to decouple the inner surface 36 of the bottom 38 of the pot 34 and the bottom surface 46 of the lower portion 48 of the removable sample sleeve 14 when the space of the removable sample sleeve 14 needs to be serviced. In certain embodiments, the cooling system 10 is configured to allow the bottom surface 46 of the lower portion 48 of the removable sample sleeve 14 to reach at least 300 Kelvin for servicing when the liquid thermal switch 42 is removed. The particular temperature to which the removable sample sleeve 14 is heated may depend on a number of factors, some or all of which may be monitored as described herein. For instance, the temperature to which the removable sample sleeve 14 is heated may depend on an amount of ice present within the removable sample sleeve 14, the pressure within the removable sample sleeve 14, or any combination of these and/or other factors. The servicing of the removable sample sleeve 14 can occur around the pot 34, that is without having to empty the cryogenic chamber (assuming a reasonable vacuum in the interspatial space 74 during the removable sample sleeve 14 warm up). In addition, the removable sample sleeve 14 can be easily removed. Utilization of the liquid thermal switch 42 (i.e., its removal during servicing) reduces down time during servicing from 3 to 4 days to less than 2 hours.

The introduction of the samples 12, formation of the liquid thermal switch 42, and similar procedures may be controlled and adjusted in response to certain detected parameters of the cooling system 10. To provide for such control, in some embodiments, the cooling system 10 may include one or more sensors 60 that detect various properties of the cooling system 10 such as temperature, pressure, and a status of the sample 12 (e.g., location within the cooling system 10 and/or whether the sample has broken). In the illustrated embodiment, the sensors 60 are communicatively coupled to a controller 62 that includes a processor 64 and memory 66. The memory 66 may include instructions that may be accessed and executed by the processor 64. By way of non-limiting example, the memory 66 may include instructions that, when executed by the processor 64, cause the controller 62 to form, to maintain, and/or to remove the liquid thermal switch 42. For example, when certain values of temperature, pressure, or both of temperature and pressure are detected by the sensors 60, the processor 64 may evaluate such temperatures and/or pressures and cause removal of the liquid thermal switch 42 in response to determining that servicing of the removable sample space is appropriate. The processor 64 may also monitor one or more these measured parameters during the formation of the liquid thermal switch 42. As another example, the sensors 60 may provide feedback to the controller 62 that is indicative of mechanical failure of a container of the sample 12, and the processor 64 may cause removal of the sample 12 from the removable sample sleeve 14, removal of the liquid thermal switch 42, or similar actions. Besides the sensors 60 (and pressure sensor 98), the valves 82, 86, 90, 94, 102 and the pump 96 are communicatively coupled to controller 62. The controller 62 provides control signals to actuate the valves 82, 86, 90, 94, 102 and turn on/off the pump 96.

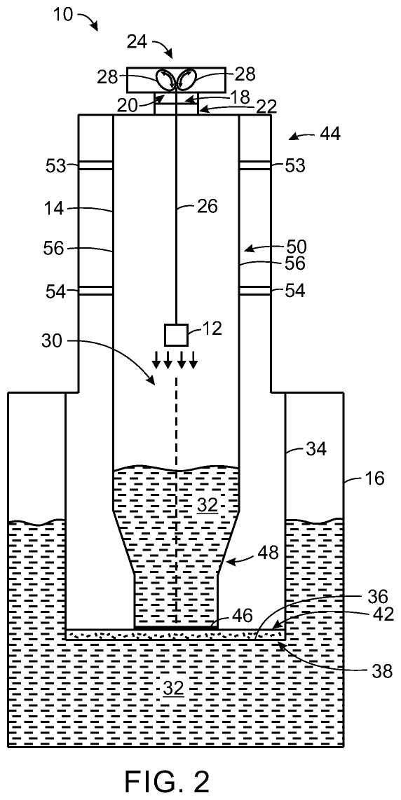

FIG. 2 is schematic diagram of the cooling system 10 (e.g., without the system 70 shown) illustrating the sample 12 being lowered toward the pot 34 for cooling. As described above, the sample 12 may be moved via the positioning system 24. As depicted, the liquid thermal switch 42 is formed between the inner surface 36 of the bottom 38 of the pot 34 and the bottom surface 46 of the lower portion 48 of the removable sample sleeve 14.

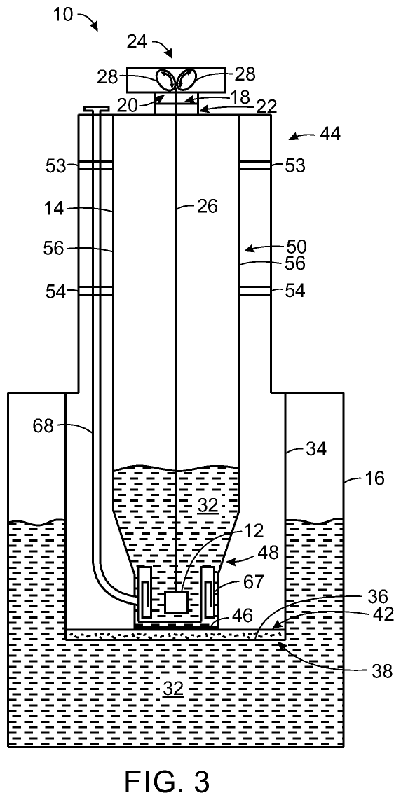

FIG. 3 is another schematic diagram of the cooling system 10 (e.g., without the system 70 shown), after the temperature within the pot 34 has reached a temperature suitable for cooling the sample 12, the sample 12 may be cooled. After the sample 12 has been suitably cooled and positioned inside the nuclear magnetic resonance coil 67, microwaves may be directed onto the sample 12 through the waveguide 68 to perform DNP.

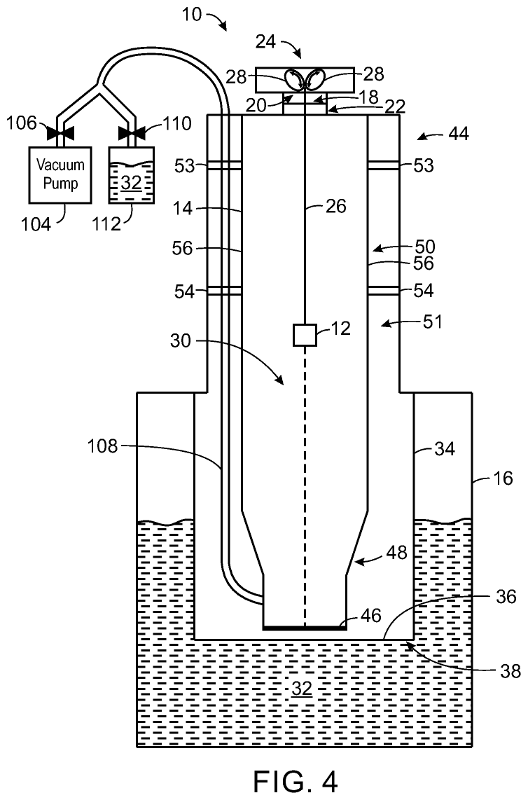

FIG. 4 is a schematic diagram of the cooling system 10 (e.g., without the system 70 shown) in which the liquid thermal switch 42 (e.g., superfluid helium) has been removed (e.g., for servicing the removable sample sleeve 14) and the interspatial space evacuated. Removal of the liquid thermal switch 42 may cause the bottom surface 46 of the removable sample sleeve 14 to warm, for example to room temperature. As also illustrated, the increase in temperature may cause some or all of the cryogenic fluid 32 within the removable sample sleeve to become gaseous. For example, the cryogenic fluid 32 may include liquid helium, and the liquid helium may evaporate as a result of the heating. The evaporated cryogenic fluid 32 and any contaminants in the removable sample sleeve 14 may be removed, and more cryogenic fluid 32 may be added to the removable sleeve 14. For example, the evaporated cryogenic fluid 32 and contaminants may be removed via a vacuum pump 104 by opening a valve 106 on a tube 108 that is connected to the removable sample sleeve 14. Additionally, cryogenic fluid 32 may be added to the removable sample sleeve 14 by opening a valve 110 associated with the external source 112 of gaseous cryogenic fluid 32. While the tube 108 is illustrated as being coupled to the lower portion 48 of the removable sample sleeve 14, the tube 108 may be coupled to other locations along the removable sample sleeve 14 in other embodiments (e.g., the body portion 50 or the upper portion 51 or the gate valve 22).

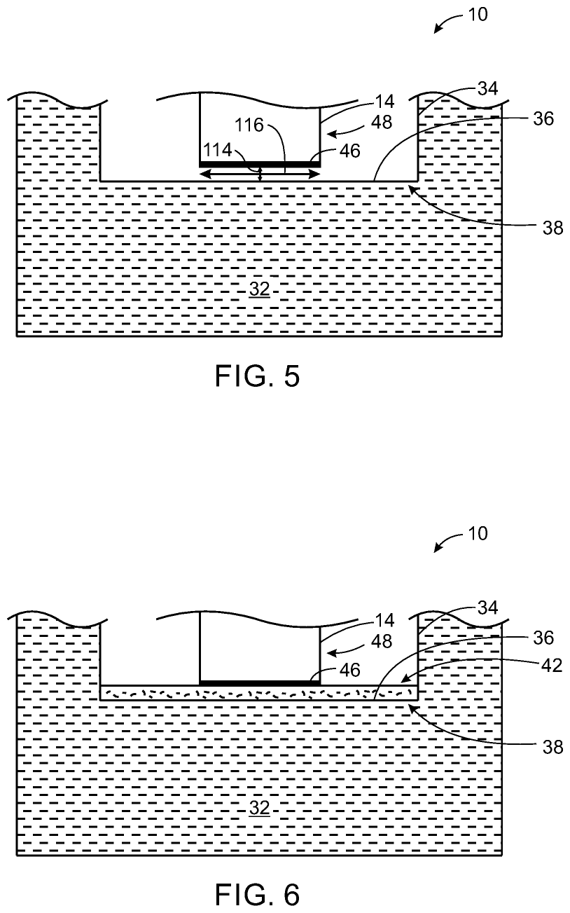

FIGS. 5 and 6 are schematic diagrams of a portion of the cooling system in FIG. 1. In FIG. 5, the liquid thermal switch 42 is absent (e.g., removed). In FIG. 6, the liquid thermal switch is present. As depicted in FIG. 5, a gap 114 is present between where the inner surface 36 of a bottom 38 of the pot 34 interfaces with the bottom surface 46 of the lower portion 48 of the removable sample sleeve 14. The gap 114 extends a length 116 of the interface between the inner surface 36 of a bottom 38 of the pot 34 and the bottom surface 46 of the lower portion 48 of the removable sample sleeve 14. In certain embodiments, the gap 114 is between 1 to 3 millimeters. In the absence of the liquid thermal switch 42 in FIG. 5, the inner surface 36 of a bottom 38 of the pot 34 and the bottom surface 46 of the lower portion 48 of the removable sample sleeve 14 are completely decoupled (e.g., physically and thermally). In the presence of the liquid thermal switch 42 in FIG. 6, the lower portion 48 of the removable sample sleeve 14 is in thermal communication with the liquid thermal switch 42 formed of superfluid helium. In particular, the liquid thermal switch 42 is disposed between and directly contacts the inner surface 36 of the bottom 38 of the pot 34 and the bottom surface 46 of the lower portion 48 of the removable sample sleeve 14. More specifically, the liquid thermal switch 42 is disposed within the gap 114 in FIG. 5 between the inner surface 36 of the bottom 38 of the pot 34 and the bottom surface 46 of the lower portion 48 of the removable sample sleeve 14. In certain embodiments, the amount of superfluid helium forming the liquid thermal switch 42 may range between approximately 2.5 to 4 milliliters.

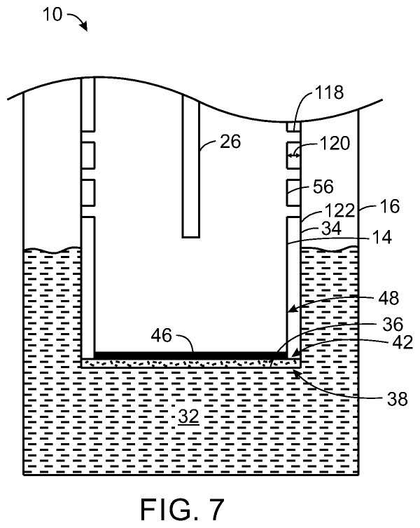

FIG. 7 is a schematic diagram of a portion of the cooling system 10 (e.g., with the removable sample sleeve 14 having thermal radiation baffles 118). As depicted, the removable sample sleeve 14 includes the wall 56. As depicted, a plurality of thermal radiation baffles 118 are disposed about and extending away from the wall 56 toward the pot 34 (e.g., across a gap 120 between the wall 56 and a sidewall 122 of the pot 34). The plurality of thermal radiation baffles 118 are disposed on the lower portion 48 of the removable sample sleeve 14 above where the liquid thermal switch 42 is located and are configured to keep superfluid helium of the liquid thermal switch 42 between the inner surface 36 of the bottom 38 of the pot 34 and the bottom surface 46 of the lower portion 48 of the removable sample sleeve 14. The thermal radiation baffles 118 prevent the runaway effect (i.e., uncontrollable flow or creep of the superfluid helium) away from its desired location (i.e., between the inner surface 36 of a bottom 38 of the pot 34 and the bottom surface 46 of the lower portion 48 of the removable sample sleeve 14).

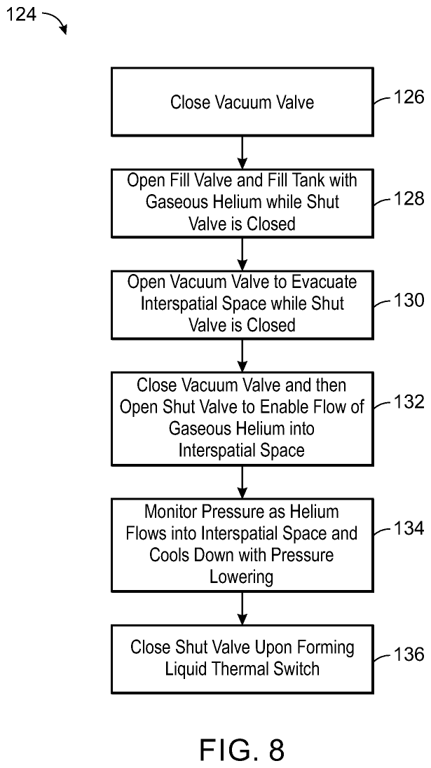

FIG. 8 is a flowchart of a method 124 for forming a thermal heat switch in the cooling system 10 in FIG. 1. The method 124 may be performed by one or more components (e.g., controller 62) of the cooling system 10 in FIG. 1.

The method 124 includes closing a vacuum valve (e.g., valve 94 in FIG. 1) (block 126). The method 124 also includes opening a fill valve (e.g., valve 82 in FIG. 1) and filling a tank (e.g., buffer tank 76 in FIG. 1) with gaseous helium while a shut valve is closed (e.g., valve 90 in FIG. 1) (block 128). The method 124 further includes opening the vacuum valve to evacuate an interspatial space between a pot and a removable sample sleeve while the shut valve is closed (block 130). The pot is positioned within a cryogenic chamber, the pot is at least partially surrounded by a cryogenic fluid, and the removable sample sleeve is inserted into the pot so that a lower portion of the removable sample sleeve is positioned in the pot and an upper portion of the removable sample sleeve protrudes out of the pot. The interspatial space is coupled to a main conduit coupled to the pot, the vacuum valve is disposed along a first interconnecting conduit coupled to the main conduit and a vacuum pump, and the shut valve is disposed along a second interconnecting conduit extending between the main conduit and a buffer tank holding a gaseous helium, and wherein the pot and the removable sample sleeve are part of the cooling system 10 associated with a dynamic nuclear polarization system. The cooling system 10 is configured to cool a sample to a temperature suitable for dynamic nuclear polarization to be carried out on the sample while the sample is in the cooling system 10.

The method 124 also includes, after evacuating the interspatial space, closing the vacuum valve and then opening the shut valve to enable flow gaseous helium into the interspatial space from the tank via the main conduit (block 132). The method 124 further includes monitoring pressure as the gaseous helium flows into the interspatial space and cools down with the pressure lowering (block 134). The method 124 even further includes closing the shut valve after helium becomes superfluid helium at a temperature of approximately 1 Kelvin forming a liquid thermal switch disposed between and directly contacting an inner surface of a bottom of the pot and a bottom surface of the lower portion of the removable sample sleeve (block 136). The removable sample sleeve is configured to define a sample path for the sample within the cryogenic chamber that is isolated from other parts of the cooling system.

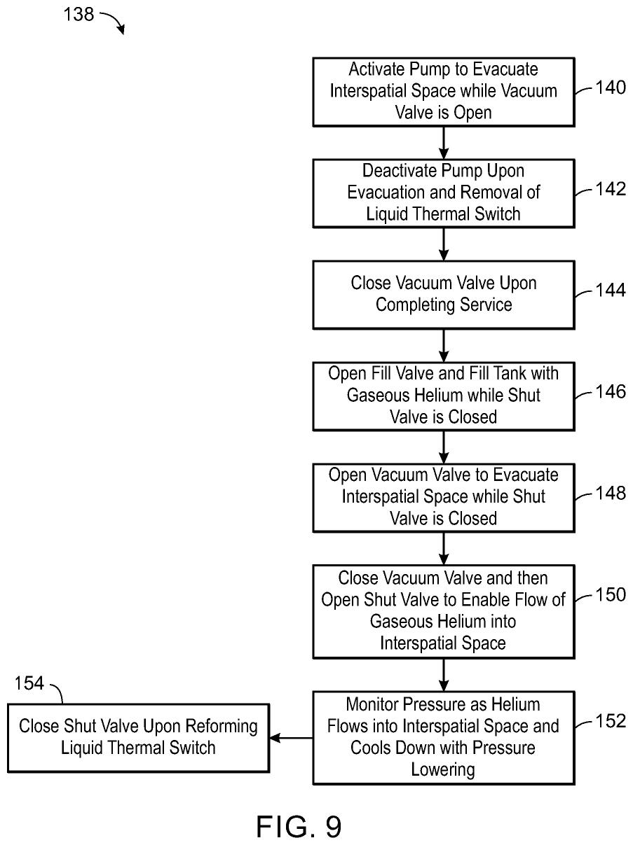

FIG. 9 is a flowchart of a method 138 for removing a thermal heat switch in the cooling system 10 in FIG. 1 (e.g., for servicing a removable sample sleeve). The method 138 may be performed by one or more components (e.g., controller 62) of the cooling system 10 in FIG. 1.

The method 138 includes, when needing servicing of space within the removable sample sleeve, activating a pump (e.g., pump 96 in FIG. 1) coupled to the first interconnecting conduit to evacuate the interspatial space and to remove the liquid thermal switch while a vacuum valve (e.g., valve 94 in FIG. 1) is open (block 140) The method 138 includes, upon evacuation of the interspatial space and removal of the liquid thermal switch, deactivating the pump (block 142). Upon evacuation of the interspatial space and removal of the liquid thermal switch, the inner surface of the bottom of the pot and the bottom surface of the lower portion of the removable sample sleeve are decoupled and the bottom surface of the lower portion of the removable sample sleeve reaches at least 300 Kelvin for servicing.

The method 138 includes, upon completing servicing, closing the vacuum valve (block 144). The method 138 also includes opening a fill valve (e.g., valve 82 in FIG. 1) and filling a tank (e.g., buffer tank 76 in FIG. 1) with gaseous helium while a shut valve is closed (e.g., valve 90 in FIG. 1) (block 146). The method 138 further includes opening the vacuum valve to evacuate an interspatial space between a pot and a removable sample sleeve while the shut valve is closed (block 148).

The method 138 also includes, after evacuating the interspatial space, closing the vacuum valve and then opening the shut valve to enable flow gaseous helium into the interspatial space from the tank via the main conduit (block 150). The method 138 further includes monitoring pressure as the gaseous helium flows into the interspatial space and cools down with the pressure lowering (block 152). The method 138 even further includes closing the shut valve after helium becomes superfluid helium at a temperature of approximately 1 Kelvin reforming the liquid thermal switch disposed between and directly contacting an inner surface of a bottom of the pot and a bottom surface of the lower portion of the removable sample sleeve (block 154).

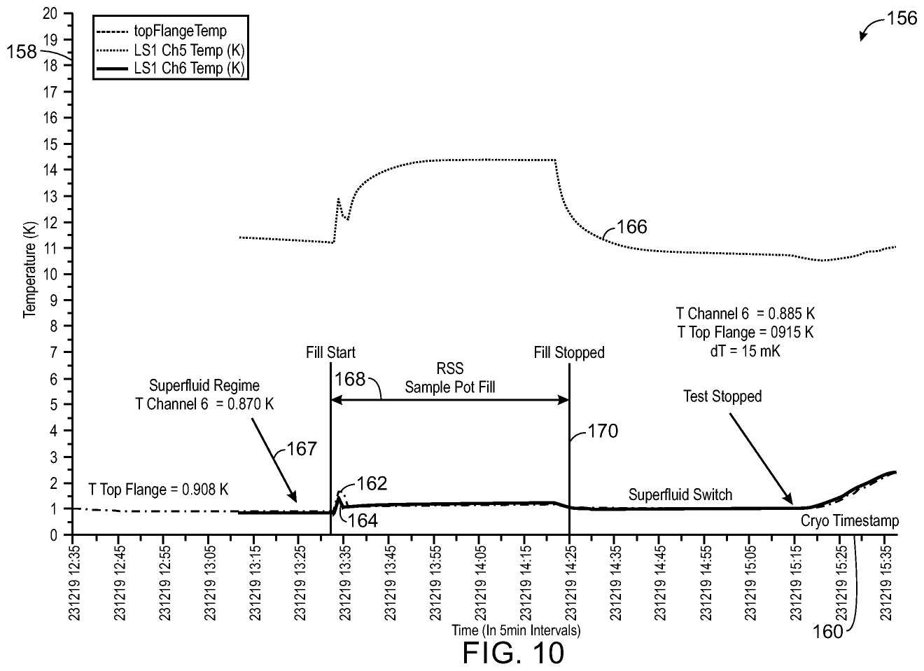

FIG. 10 is a graph 156 depicting temperatures near a top portion (e.g., top flange) of a cryogenic vessel that a removable sample sleeve is partially disposed within and a bottom of the removable sample sleeve (e.g., at a bottom surface of the lower portion of the removable sample sleeve that interfaces with the liquid thermal switch which is interfacing with an inner surface of a bottom of a pot) in a presence of a liquid thermal switch. The graph 156 includes a y-axis 158 representing temperature in Kelvin (K). The graph 156 also includes an x-axis 160 representing time in 5 minute (min) intervals. Plot 162 represents a temperature of the top flange (T top flange). The top flange sensor is mounted on the cryogenic chamber (e.g., cryogenic chamber 16 in FIG. 1 near arrow 74). Plot 164 represents a channel 6 temperature profile (T channel 6) outside the removable sample sleeve (e.g., near where arrow 46 in FIG. 1 is located). Plot 166 represents a channel 5 temperature profile higher up the removable sample sleeve relative to channel 6 and the top flange sensor, thus, accounting for the temperature difference between plot 166 and the plots 162, 164. With the liquid thermal switch established (i.e., superfluid regime) and prior to filling of a sample pot (i.e., bottom of removable sample sleeve) with cryogenic fluid (as indicated by arrow 167), the temperature of the top flange is 0.904 K and temperature at the bottom of the removable sample sleeve is 0.866 K. Arrow 168 indicates the time period when the sample pot is filled with cryogenic fluid. During the filling, the base temperature increases as indicated by plot 166. Line 170 indicates when the filling of the sample pot with the cryogenic fluid stopped. After the filling, the temperature of the top flange is 1.021 K and temperature at the bottom of the removable sample sleeve is 0.999 K. In other words, the liquid thermal switch (e.g., superfluid helium) essentially eliminates the temperature difference between surfaces at 1 K via its infinite thermal conductivity.

Technical effects of the disclosed embodiments include providing a cooling system a cooling system associated with a dynamic nuclear polarization system that utilizes a liquid thermal switch (e.g., superfluid helium). Technical effects of the disclosed embodiments include enabling the removal of a thermal switch made of mechanical parts and any other mechanical components associated with such a thermal switch. Technical effects of the disclosed embodiments include the liquid thermal switch providing perfect contact (between the two contact surfaces) in a cryogenic environment without mechanical means utilizing the high thermal conductivity of superfluid helium. Technical effects of the disclosed embodiments include enabling faster service with a reduction in down time for a cooling system.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

This written description uses examples to disclose the present subject matter, including the best mode, and also to enable any person skilled in the art to practice the subject matter, including making and using any devices or systems and performing any incorporated methods. The patentable scope of the subject matter is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A cooling system associated with a dynamic nuclear polarization system, wherein the cooling system is configured to cool a sample to a temperature suitable for dynamic nuclear polarization to be carried out on the sample while the sample is in the cooling system, and wherein the cooling system comprises:
a cryogenic chamber comprising a cryogenic fluid:
a pot positioned within the cryogenic chamber, the pot being at least partially surrounded by the cryogenic fluid;
a removable sample sleeve inserted into the pot so that a lower portion of the removable sample sleeve is positioned in the pot and an upper portion of the removable sample sleeve protrudes out of the pot, and wherein the removable sample sleeve is configured to define a sample path for the sample within the cryogenic chamber that is isolated from other parts of the cooling system; and
a liquid thermal switch configured to be disposed between and directly contact an inner surface of a bottom of the pot and a bottom surface of the lower portion of the removable sample sleeve, wherein the liquid thermal switch comprises superfluid helium.

2. The cooling system of claim 1, wherein the liquid thermal switch is configured to be disposed within a gap between the inner surface of the bottom of the pot and the bottom surface of the lower portion of the removable sample sleeve.

3. The cooling system of claim 2, wherein gap is between 1 to 3 millimeters.

4. The cooling system of claim 1, wherein the liquid thermal switch is configured to keep a same temperature at the inner surface of the bottom of the pot and at the bottom surface of the lower portion of the removable sample sleeve by providing infinite thermal conductivity between the inner surface of the bottom of the pot and the bottom surface of the lower portion of the removable sample sleeve at a temperature below 2.5 Kelvin.

5. The cooling system of claim 4, wherein the liquid thermal switch is configured to compensate for surface irregularities that cause the inner surface of the bottom of the pot and the bottom surface of the lower portion of the removable sample sleeve to not be perfectly parallel along a length of interface between the inner surface and the bottom surface, and wherein the liquid thermal switch is configured to compensate for build tolerances between the inner surface of the bottom of the pot and the bottom surface of the lower portion of the removable sample sleeve.

6. The cooling system of claim 4, wherein the liquid thermal switch is configured to provide near zero thermal resistance between the inner surface of the bottom of the pot and the bottom surface of the lower portion of the removable sample sleeve.

7. The cooling system of claim 1, wherein the cooling system is configured to remove the liquid thermal switch to decouple the inner surface of the bottom of the pot and the bottom surface of the lower portion of the removable sample sleeve.

8. The cooling system of claim 7, wherein the cooling system is configured to allow the bottom surface of the lower portion of the removable sample sleeve to reach at least 300 Kelvin for servicing when the liquid thermal switch is removed.

9. The cooling system of claim 1, wherein the removable sample sleeve comprises a wall and one or more thermal radiation baffles disposed about and extending away from the wall toward the pot, wherein the one or more thermal radiation baffles are disposed on the lower portion of the removable sample sleeve above where the liquid thermal switch is located and are configured to keep superfluid helium of the liquid thermal switch between the inner surface of the bottom of the pot and the bottom surface of the lower portion of the removable sample sleeve.

10. A method for regulating a liquid thermal switch for a cooling system associated with a dynamic nuclear polarization system, wherein the cooling system is configured to cool a sample to a temperature suitable for dynamic nuclear polarization to be carried out on the sample while the sample is in the cooling system, comprising:
opening, via a processor, a vacuum valve to evacuate an interspatial space between a pot and a removable sample sleeve while a shut valve is closed, wherein the pot is positioned within a cryogenic chamber, the pot is at least partially surrounded by a cryogenic fluid, and the removable sample sleeve is inserted into the pot so that a lower portion of the removable sample sleeve is positioned in the pot and an upper portion of the removable sample sleeve protrudes out of the pot, wherein the removable sample sleeve is configured to define a sample path for the sample within the cryogenic chamber that is isolated from other parts of the cooling system, and wherein the interspatial space is coupled to a main conduit coupled to the pot, the vacuum valve is disposed along a first interconnecting conduit coupled to the main conduit and a vacuum pump, and the shut valve is disposed along a second interconnecting conduit extending between the main conduit and a buffer tank holding a gaseous helium;
after evacuating the interspatial space, closing, via the processor, the vacuum valve and then opening, via the processor, the shut valve to enable flow gaseous helium into the interspatial space from the buffer tank via the main conduit;
monitoring, via the processor, pressure as the gaseous helium flows into the interspatial space and cools down with the pressure lowering; and
closing, via the processor, the shut valve after helium becomes superfluid helium at a temperature of approximately 1 Kelvin forming the liquid thermal switch disposed between and directly contacting an inner surface of a bottom of the pot and a bottom surface of the lower portion of the removable sample sleeve.

11. The method of claim 10, further comprising, when needing servicing of space within the removable sample sleeve, activating, via processor, a pump coupled to the first interconnecting conduit to evacuate the interspatial space and to remove the liquid thermal switch while the vacuum valve is open, wherein, upon evacuation of the interspatial space and removal of the liquid thermal switch, the inner surface of the bottom of the pot and the bottom surface of the lower portion of the removable sample sleeve are decoupled and the bottom surface of the lower portion of the removable sample sleeve reaches at least 300 Kelvin for servicing.

12. The method of claim 10, wherein the liquid thermal switch keeps a same temperature at the inner surface of the bottom of the pot and at the bottom surface of the lower portion of the removable sample sleeve by providing infinite thermal conductivity between the inner surface of the bottom of the pot and the bottom surface of the lower portion of the removable sample sleeve at a temperature below 2.5 Kelvin.

13. The method of claim 10, wherein the liquid thermal switch compensates for surface irregularities that cause the inner surface of the bottom of the pot and the bottom surface of the lower portion of the removable sample sleeve to not be perfectly parallel along a length of interface between the inner surface and the bottom surface, and wherein the liquid thermal switch compensates for build tolerances between the inner surface of the bottom of the pot and the bottom surface of the lower portion of the removable sample sleeve.

14. The method of claim 10, wherein the liquid thermal switch provides near zero thermal resistance between the inner surface of the bottom of the pot and the bottom surface of the lower portion of the removable sample sleeve.

15. The method of claim 10, wherein the liquid thermal switch is disposed within a gap between the inner surface of the bottom of the pot and the bottom surface of the lower portion of the removable sample sleeve, and the gap between 1 to 3 millimeters.

16. A non-transitory computer-readable medium, the computer-readable medium comprising processor-executable code that when executed by a processing system comprising one or more processors, causes the processing system to:
open a vacuum valve to evacuate an interspatial space between a pot and a removable sample sleeve while a shut valve is closed, wherein the pot is positioned within a cryogenic chamber, the pot is at least partially surrounded by a cryogenic fluid, and the removable sample sleeve is inserted into the pot so that a lower portion of the removable sample sleeve is positioned in the pot and an upper portion of the removable sample sleeve protrudes out of the pot, wherein the interspatial space is coupled to a main conduit coupled to the pot, the vacuum valve is disposed along a first interconnecting conduit coupled to the main conduit and a vacuum pump, and the shut valve is disposed along a second interconnecting conduit extending between the main conduit and a buffer tank holding a gaseous helium, and wherein the pot and the removable sample sleeve are part of a cooling system associated with a dynamic nuclear polarization system, wherein the cooling system is configured to cool a sample to a temperature suitable for dynamic nuclear polarization to be carried out on the sample while the sample is in the cooling system, and wherein the removable sample sleeve is configured to define a sample path for the sample within the cryogenic chamber that is isolated from other parts of the cooling system;
after evacuating the interspatial space, close the vacuum valve and then open the shut valve to enable flow gaseous helium into the interspatial space from the buffer tank via the main conduit;
monitor pressure as the gaseous helium flows into the interspatial space and cools down with the pressure lowering; and
close the shut valve after helium becomes superfluid helium at a temperature of approximately 1 Kelvin forming a liquid thermal switch disposed between and directly contacting an inner surface of a bottom of the pot and a bottom surface of the lower portion of the removable sample sleeve.

17. The non-transitory computer-readable medium of claim 16, wherein the processor-executable code, when executed by the processing system, further causes the processing system, when needing servicing of space within the removable sample sleeve, to activate a pump coupled to the first interconnecting conduit to evacuate the interspatial space and to remove the liquid thermal switch while the vacuum valve is open, wherein, upon evacuation of the interspatial space and removal of the liquid thermal switch, the inner surface of the bottom of the pot and the bottom surface of the lower portion of the removable sample sleeve are decoupled and the bottom surface of the lower portion of the removable sample sleeve reaches at least 300 Kelvin for servicing.

18. The non-transitory computer-readable medium of claim 16, wherein the liquid thermal switch keeps a same temperature at the inner surface of the bottom of the pot and at the bottom surface of the lower portion of the removable sample sleeve by providing infinite thermal conductivity between the inner surface of the bottom of the pot and the bottom surface of the lower portion of the removable sample sleeve at a temperature below 2.5 Kelvin.

19. The non-transitory computer-readable medium of claim 16, wherein the liquid thermal switch compensates for surface irregularities that cause the inner surface of the bottom of the pot and the bottom surface of the lower portion of the removable sample sleeve to not be perfectly parallel along a length of interface between the inner surface and the bottom surface, and wherein the liquid thermal switch compensates for build tolerances between the inner surface of the bottom of the pot and the bottom surface of the lower portion of the removable sample sleeve.

20. The non-transitory computer-readable medium of claim 16, wherein the liquid thermal switch provides near zero thermal resistance between the inner surface of the bottom of the pot and the bottom surface of the lower portion of the removable sample sleeve.
